(19) United States
(12) Patent Application Publication
(10) Pub. No.: US 2026/0307508 A1
(43) Pub. Date: Oct. 8, 2026

(54) WIRELESS BATTERY MANAGEMENT SYSTEM HAVING A POWER REDUNDANCY STRUCTURE AND A METHOD FOR OPERATING THE SAME

(71) Applicants: HYUNDAI MOTOR COMPANY, Seoul (KR); KIA CORPORATION, Seoul (KR)

(72) Inventors: Naeun Song, Hwaseong-si (KR); Jonghu Yoon, Hwaseong-si (KR); Jun Baek, Hwaseong-si (KR)

(73) Assignees: HYUNDAI MOTOR COMPANY, Seoul (KR); KIA CORPORATION, Seoul (KR)

(21) Appl. No.: 19/337,600

(22) Filed: Sep. 23, 2025

(30) Foreign Application Priority Data
Apr. 7, 2025 (KR) 10-2025-0044672

(51) Int. Cl. B60L 50/60; B60R 16/023; G01R 31/382; G01R 31/396

(52) U.S. Cl. CPC B60L 50/60; B60R 16/023; G01R 31/382; G01R 31/396; B60L 2210/12; B60L 2260/22

(57) ABSTRACT

A wireless battery management system having a continuous battery cell monitoring function includes at least one cell monitoring unit (CMU) configured to monitor a state of each battery module, among one or more battery modules, in a battery system. The wireless battery management system also includes a battery management unit (BMU) configured to determine whether a battery cell included in each battery module, among the one or more battery modules, is abnormal based on cell state information monitored by the CMU. The wireless battery management includes a power supply unit configured to supply power in two or more different ways to a wireless communication interface unit that is configured to support wireless communication between the CMU and the BMU.

### CROSS-REFERENCE TO RELATED APPLICATION

The present application claims the benefit of and priority to Korean Patent Application No. 10-2025-0044672, filed on Apr. 7, 2025, in the Korean Intellectual Property Office, the entire contents of which are hereby incorporated herein by reference.

### TECHNICAL FIELD

The present disclosure relates to a battery management system and a method for operating the same. More particularly, the present disclosure relates to a wireless battery management system having a power redundancy structure that, while reducing increases in size and cost, may be configured to supply redundant power to a communication interface for monitoring battery cells when an electric vehicle is parked, and to a method for operating the wireless battery management system.

### BACKGROUND

Batteries used in environmentally friendly vehicles such as electric vehicles (EVs), hybrid electric vehicles (HEVs), and plug-in hybrid electric vehicles (PHEVs) are high-voltage batteries that generate high voltage by connecting numerous battery cells having the same specifications in series/parallel.

A battery management system (BMS) is a device that controls and manages charging and discharging of such high-voltage batteries including numerous battery cells. The BMS includes at least one cell monitoring unit (CMU) configured to monitor the battery cells, a battery management unit (BMU) configured to manage the at least one CMU, and the like.

The BMU of the BMS may need to continuously monitor the battery cells and detect and respond to any abnormalities even while an electric vehicle is parked after Ignition-Off (IG OFF).

To this end, in the related art, based on wireless BMS technology that supports wireless communication between the CMU and the BMU, reverse Wake-Up functionality is applied to allow the BMS to wake up only in risk situations of battery cells while the electric vehicle is parked.

To implement the reverse Wake-Up function, a communication bridge integrated circuit (IC) (e.g., ADBMS6822) for wireless communication may be applied to the BMU and the WCM (wireless communication module) in the BMS. Each communication bridge IC (e.g., ADBMS6822) may include two independent integrated circuits or DIEs and may require a power redundancy design for communication stability.

Accordingly, in the related art, the reverse Wake-Up function enables continuous monitoring of battery cells even during IG OFF while the electric vehicle is parked, but there is an issue in that the size of the BMS increases and the cost rises due to the power redundancy structure for supplying power to the communication bridge IC in the BMU.

The matters described in this Background section are merely for enhancement of understanding of the background of the present disclosure, and should not be taken as acknowledgement that the matters include prior art already known to those having ordinary skill in the art.

### SUMMARY

The following summary presents a simplified summary of certain features. The summary is not an extensive overview and is not intended to identify key or critical elements.

Embodiments of the present disclosure is provide a wireless battery management system having a power redundancy structure that, while reducing increases in size and cost, may be configured to redundantly supply power to a communication interface (e.g., a communication bridge integrated circuit (IC) of a battery management unit (BMU)) used for monitoring battery cells during Ignition-Off (IG OFF) when an electric vehicle is parked, and to a method for operating the wireless battery management system.

In addition, embodiments of the present disclosure provide a wireless battery management system having a power redundancy structure and a method for operating the same, wherein the power redundancy structure may enable reliable monitoring of battery cells even when the continuous power supply to a communication interface (e.g., a communication bridge IC of the BMU) is abnormal.

Aspects of the present disclosure are not limited to those mentioned above. Other aspects and advantages not mentioned herein should be more clearly understood from the following description by those having ordinary skill in the art, and become more apparent from the described embodiments. Moreover, aspects of the present disclosure may be realized by the means and combinations thereof indicated in claims.

According to an aspect of the present disclosure, a wireless battery management system having a power redundancy structure is provided. The wireless battery management system includes at least one cell monitoring unit (CMU) configured to monitor a state of each battery module, among one or more battery cells, in a battery system. The wireless battery management system also includes a battery management unit (BMU) configured to determine whether a battery cell included in each battery module, among the one or more battery modules, is abnormal based on cell state information monitored by the CMU. The wireless battery management system additionally includes a power supply unit configured to supply power in two or more different ways to a wireless communication interface unit that is configured to support wireless communication between the CMU and the BMU.

The power supply unit may include a DCDC converter configured to supply continuous power to the wireless communication interface unit, and a system basis chip (SBC) configured to step down input power from a vehicle to a voltage level suitable for each component within the BMU and to supply the stepped-down input power to each component.

The wireless communication interface unit may include a first communication bridge IC implemented in a wireless communication module (WCM) and configured to perform wireless communication with the CMU, and a second communication bridge IC implemented in the BMU and configured to receive cell state information from the CMU through communication with the first communication bridge IC.

The second communication bridge IC may include two independent dies (DIEs) configured to communicate with the first communication bridge IC. The power supply unit may include a DCDC converter and an SBC, where the DCDC converter and the SBC is each configured to supply power to a corresponding one DIE among the two independent DIEs.

During an active mode of the BMU, respective power from the DCDC converter and the SBC may be supplied to each of the two DIEs included in the second communication bridge IC, and during a Sleep Mode of the BMU, power from one of the DCDC converter or the SBC may be supplied to one of the two DIEs.

According to another aspect of the present disclosure, a battery management unit (BMU) having a power redundancy structure is provided. The BMU includes a control unit configured to receive cell state information from at least one cell monitoring unit (CMU)—the CMU being configured to monitor a state of each battery module—and to determine, based on the cell state information, whether a battery cell included in each battery module, among one or more battery modules, is abnormal. The BMU also includes a power supply unit configured to supply power in two or more different ways to a wireless communication interface unit that is configured to support wireless communication between the CMU and the BMU.

The wireless communication interface unit may include a first communication bridge IC implemented in a wireless communication module (WCM) and configured to perform wireless communication with the CMU, and a second communication bridge IC implemented in the BMU and configured to receive cell state information from the CMU through communication with the first communication bridge IC.

The first communication bridge IC may include two DIEs. Each of the two DIEs may communicate in a one-to-one manner with a corresponding DIE within the second communication bridge IC. If the continuous power supply by the DCDC converter operates abnormally, the first communication bridge IC may be configured to communicate only through one of the two DIEs within the first communication bridge IC that communicates with a DIE, within the second communication bridge IC, that is supplied with power from the SBC.

The control unit may be configured to, based on being woken up during the Sleep Mode of the BMU by the wireless communication interface unit operating with continuous power from the DCDC converter, i) receive cell state information from all CMUs through the wireless communication interface unit and ii) determine, based on the received cell state information, whether each battery cell is abnormal.

The control unit may be configured to, based on a time when the SBC is periodically woken up during the Sleep Mode of the BMU, i) receive cell state information from all CMUs through the wireless communication interface unit operating with power supplied from the SBC, and ii) determine, based on the received cell state information, whether each battery cell is abnormal.

According to still another aspect of the present disclosure, a method for operating a wireless battery management system (BMS) having a power redundancy structure is provided. The method includes continuously monitoring, by at least one cell monitoring unit (CMU), a state of each battery module among one or more battery modules. The method also includes determining, by a battery management unit (BMU), whether a battery cell included in each battery module, among the one or more battery modules, is abnormal based on cell state information monitored by the at least one CMU. The method additionally includes operating a wireless communication interface unit in the BMU using power supplied from at least one of a DCDC converter that provides continuous power and a system basis chip (SBC), wherein the wireless communication interface unit is configured to support wireless communication between the CMU and the BMU.

The wireless communication interface unit may include a first communication bridge IC implemented in a wireless communication module (WCM) and configured to perform wireless communication with the CMU, and a second communication bridge IC implemented in the BMU and configured to receive cell state information from the CMU through communication with the first communication bridge IC.

The method may further include determining, by a control unit of the BMU, whether continuous power supply by the DCDC converter is operating normally after Ignition-On (IG ON), transitioning, by the control unit of the BMU, to a Sleep Mode upon Ignition-Off without a separate configuration procedure to utilize power from the SBC based on the continuous power supply being determined to be operating normally, and performing, by the control unit of the BMU, the separate configuration procedure to utilize power from the SBC based on the continuous power supply being determined to be operating abnormally, and transitioning to the Sleep Mode upon Ignition-Off.

The second communication bridge IC may include two independent DIEs that communicate with the first communication bridge IC. The first communication bridge IC may include two DIEs that communicate in a one-to-one manner with the two DIEs within the second communication bridge IC. The separate configuration procedure to utilize power from the SBC may include configuring a real-time clock (RTC) operation such that the SBC is periodically woken up and remains in a wake-up state for a predetermined period of time.

The second communication bridge IC may include two independent DIEs that communicate with the first communication bridge IC, and respective power from the DCDC converter and the SBC may be supplied to each of the two DIEs included in the second communication bridge IC. The first communication bridge IC may include two DIEs that communicate in a one-to-one manner with the two DIEs within the second communication bridge IC.

The separate configuration procedure to utilize power from the SBC may include deactivating one of the two DIEs within the first communication bridge IC. Specifically, the DIE to be deactivated may be the DIE that communicates with a DIE, within the second communication bridge IC, that is supplied with continuous power from the DCDC converter.

As described above, in the wireless BMS according to embodiments of the present disclosure, the power redundancy system may be improved by using power from the SBC, thereby enabling the configuration to operate with a single DCDC converter. In existing systems, power is supplied to the communication interface, including the communication bridge IC of the BMU, using two DCDC converters. The proposed configuration may therefore reduce the overall size and cost of the BMU.

Furthermore, according to embodiments of the present disclosure, in the power redundancy structure for the communication interface (e.g., the communication bridge IC of the BMU), even when the continuous power supply from the DCDC converter is abnormal, the battery cells may still be reliably monitored and properly managed. This enables fires caused by the battery to be addressed before progressing significantly, thereby greatly reducing damage to property and people.

### BRIEF DESCRIPTION OF THE DRAWINGS

The foregoing and other aspects, features, and advantages, as well as the following detailed description of the embodiments, should be more clearly understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIG. 1 illustrates a power redundancy structure for a communication interface (e.g., a communication bridge integrated circuit (IC) of a BMU) in an existing wireless battery management system.

FIGS. 2 to 4 illustrate, for respective cases, how power is supplied through a power redundancy structure in a wireless battery management system according to an embodiment of the present disclosure.

FIG. 5 illustrates a configuration of a BMU according to one embodiment of the present disclosure.

FIG. 6 illustrates an operation of a BMU in a wireless battery management system having a power redundancy structure according to an embodiment of the present disclosure, based on an abnormal condition of continuous power.

FIGS. 7 and 8 are flowcharts illustrating a method for operating a wireless battery management system having a power redundancy structure according to one embodiment of the present disclosure.

### DETAILED DESCRIPTION

Hereinafter, embodiments of the present document are described in detail with reference to the accompanying drawings. Like reference numerals designate like elements, and redundant descriptions thereof have been omitted. Further, suffixes such as “module” and a “unit” used for components in the following description are given or mixed and used by considering easiness in preparing the specification and do not have a meaning or role distinguished from each other in themselves. In addition, in the present disclosure, where it was determined that a detailed description of a related art incorporated herein would obscure the gist of the present disclosure, the detailed description thereof has been omitted. Furthermore, it should be understood that the appended drawings are intended only to enhance understanding of embodiments described in the present disclosure and do not limit the technical principles and scope of the present disclosure. Rather, it should be understood that the appended drawings include all of the modifications, equivalents, or substitutes described by the technical principles and belonging to the technical scope of the present disclosure.

Although the terms first, second, and the like, may be used herein to describe various elements, these elements should not be limited by these terms. These terms are generally merely used to distinguish one element from another.

When a component, unit, device, element, apparatus, or the like of the present disclosure is described as having a purpose or performing an operation, function, or the like, the component, unit, device, element, apparatus, or the like should be considered herein as being “configured to” meet that purpose or to perform that operation or function. Each component, unit, device, element, apparatus, and the like may separately embody or be included with a processor and a memory, such as a non-transitory computer readable media, as part of the apparatus.

When an element or layer is referred to as being “on,” “engaged to,” “connected to,” or “coupled to” another element or layer, it may be directly on, engaged, connected, or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, and C”, “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B.

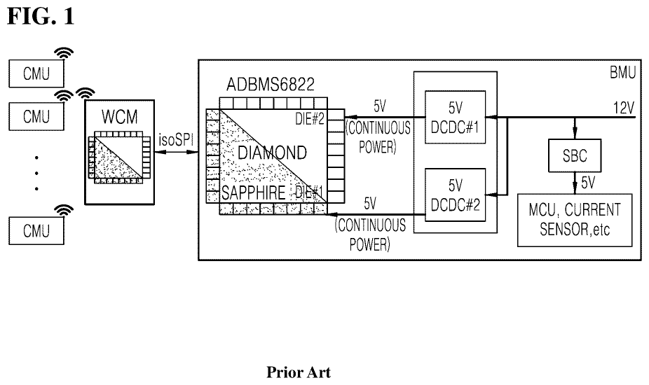

Hereinafter, a wireless battery management system having a power redundancy structure and a method for operating the same according to embodiments of the present disclosure are described in detail with reference to FIGS. 1-8.

Prior to the description of the present disclosure, a power redundancy structure for a communication interface (e.g., a communication bridge integrated circuit (IC) of a battery management unit (BMU)) in an existing wireless battery management system is described with reference to FIG. 1.

FIG. 1 illustrates a power redundancy structure for a communication interface (e.g., a communication bridge IC of the BMU) in an existing wireless battery management system.

Referring to FIG. 1, in existing technology, the BMU of a battery management system (BMS) may be configured to implement a reverse Wake-Up function that wakes up the BMS in Sleep Mode based on a risk situation of battery cells, thereby enabling continuous monitoring and response to the battery cells even during an Ignition-Off (IG OFF) state while an electric vehicle is parked.

To implement the reverse Wake-Up function, a communication bridge IC (e.g., ADBMS6822) for wireless communication may be applied to the BMU and a wireless communication module (WCM). Each communication bridge IC (e.g., ADBMS6822) may include two independent integrated circuits or dies (DIEs) and may have a power redundancy design or structure for communication stability.

Accordingly, in existing technology, in order for the BMU to continuously detect a Wake-Up signal from the WCM that has received a wireless signal from a cell monitoring unit (CMU) detecting abnormalities of a battery cell (e.g., cell 0V) while the electric vehicle is parked, continuous power is supplied to the communication bridge IC (e.g., ADBMS6822) of the BMU through two 5V direct current to direct current (DCDC) converters.

In addition, since each communication bridge IC (e.g., ADBMS6822) of the BMU and the WCM operates with two independent DIEs (#1 and #2), the system may operate using the other DIE based on a failure of one DIE.

However, in the existing technology illustrated in FIG. 1, since two 5V DCDC converters are redundantly designed in the BMU of the wireless BMS to provide power redundancy, there is an issue in that the size of the BMS increases and the cost rises.

In addition, since both DIEs (#1 and #2) in the communication bridge IC (e.g., ADBMS6822) of the BMU operate continuously, there is a concern that the quiescent current of the BMU may increase.

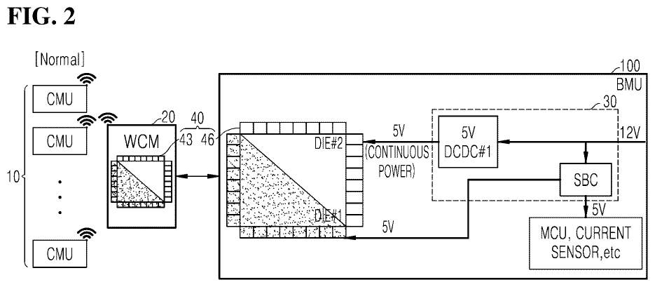

Hereinafter, with reference to FIGS. 2-4, a manner in which power is supplied through a power redundancy structure is described for respective cases in a wireless battery management system having a power redundancy structure according to embodiments of the present disclosure.

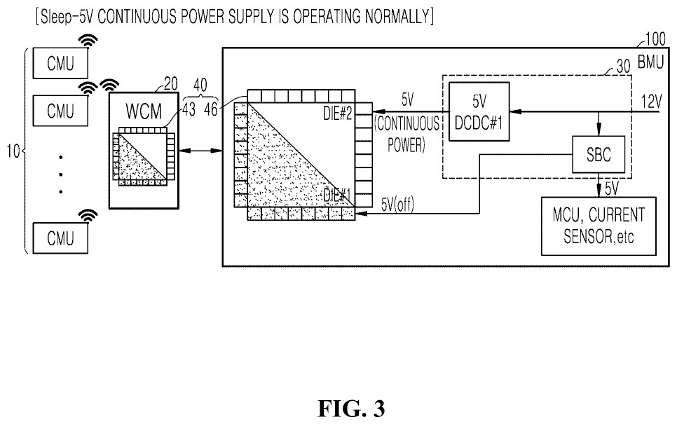

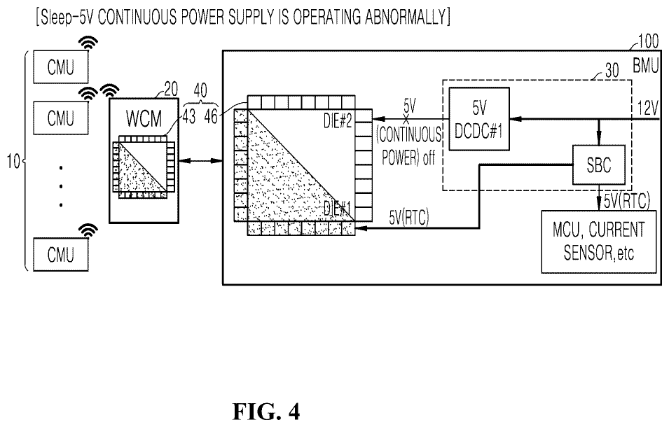

FIG. 2 illustrates a case in which a BMU is in an active mode (hereinafter referred to as “normal”) in a wireless BMS according to an embodiment of the present disclosure. FIG. 3 illustrates a case in which a BMU is in a Sleep Mode and continuous power supply is normal (hereinafter referred to as “sleep-normal 5V supply”) in a wireless BMS according to an embodiment of the present disclosure. FIG. 4 illustrates a case in which a BMU is in a Sleep Mode and continuous power supply is abnormal (hereinafter referred to as “sleep-abnormal 5V supply”) in a wireless BMS according to an embodiment of the present disclosure.

As illustrated in FIGS. 2-4, a wireless battery management system (BMS) having a power redundancy structure according to an embodiment of the present disclosure may include at least one cell monitoring unit (CMU) 10 configured to monitor a state of each battery module, among one or more battery modules, in a battery system. The wireless BMS may also include a battery management unit (BMU) 100 configured to determine whether a battery cell included in each battery module, among the one or more battery modules, is abnormal based on cell state information monitored by the CMU 10. The wireless BMS may also include may further include a power supply unit 30 configured to supply power in two or more different ways to a wireless communication interface unit 40 that is configured to support wireless communication between the CMU 10 and the BMU 100.

The wireless communication interface unit 40 may include a first communication bridge IC 43 (e.g., ADBMS6822) and a second communication bridge IC 46 (e.g., ADBMS6822). The first communication bridge IC 43 may be implemented in a wireless communication module (WCM) 20 and may be configured to perform wireless communication with CMU 10. The second communication bridge IC 46 may be implemented in the BMU 10 and may be configured to receive cell state information from the CMU 10 through communication with the first communication bridge IC 43.

In addition, as illustrated in FIGS. 2-4, the second communication bridge IC 46 may include two independent integrated circuits or DIEs #1 and #2 that communicate with the first communication bridge IC 43. Further, the first communication bridge IC 43 may include two integrated circuits or DIEs that communicate with the two DIEs #1 and #2 in the second communication bridge IC 46 in a one-to-one manner.

In particular, according to an embodiment of the present disclosure, the power supply unit 30 may include a DCDC converter (hereinafter, 5V DCDC #1) that is configured to supply continuous power to the wireless communication interface unit 40, and a system basis chip (SBC) that is configured to step down input power from a vehicle (B+LDC) to voltage levels according to the specifications of each component (e.g., MCU, current sensor, etc.) within the BMU 100 and to supply the stepped-down input power to each component.

As illustrated in FIGS. 2-4, the power supply unit 30 may include a DCDC converter (5V DCDC #1) and an SBC, each configured to supply power to a corresponding one of the two DIEs #1 and #2 in the second communication bridge IC 46.

For example, FIGS. 2-4 illustrate a connection structure in which continuous power from the 5V DCDC #1 is supplied to DIE #2 in the second communication bridge IC 46, and power from the SBC is supplied to DIE #1 in the second communication bridge IC 46.

In contrast to the existing approach (see FIG. 1) that employs two 5V DCDC converters, an embodiment of the present disclosure enables the use of only a single 5V DCDC converter by supplying 5V power from the SBC to one of the DIEs in the communication bridge IC 46 (e.g., ADBMS6822). This configuration may not only simplify the hardware design but also maintain the power redundancy structure for the communication bridge IC 46 in the BMU 100, thereby improving efficiency and reducing costs.

In this regard, referring to FIG. 2, in the wireless BMS according to an embodiment of the present disclosure, based on the above-described power redundancy structure implemented using the 5V DCDC #1 and the SBC, respective power from both the 5V DCDC #1 and the SBC is supplied to each of the two DIEs #1 and #2 included in the second communication bridge IC 46 in the active mode of the BMU 100, that is, the normal mode of the BMU 100 in which the electric vehicle is in an IG ON state.

For example, even if either power supplied from the 5V DCDC #1 or the SBC becomes unstable, the other stable power may be supplied to one DIE in the communication bridge IC 46 (e.g., ADBMS6822) included in the BMU 100. Accordingly, continuous monitoring of battery cells, abnormality determination, and corresponding control operations by the BMU 100 may be performed in a stable manner.

In the wireless BMS according to an embodiment of the present disclosure, based on the above-described power redundancy structure implemented using the 5V DCDC #1 and the SBC, in the Sleep Mode of the BMU 100—i.e., the Sleep Mode of the BMU 100 in which the electric vehicle is in an IG OFF state—power from either the 5V DCDC #1 or the SBC is supplied to one of the two DIEs #1 and #2 in the second communication bridge IC 46 included in the BMU 100.

For example, referring to FIG. 3, in the wireless BMS according to an embodiment of the present disclosure, when the power supply from the 5V DCDC #1 is operating normally in the Sleep Mode of the BMU 100, power from the 5V DCDC #1 is supplied to DIE #2 of the two DIEs #1 and #2 in the second communication bridge IC 46.

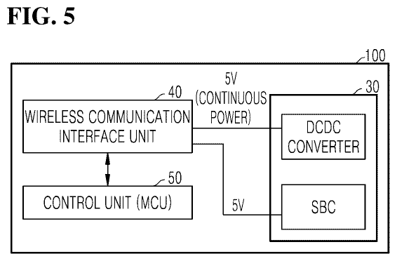

In an embodiment, a controller 50 (see FIG. 5) of the BMU 100 may be configured to continuously or periodically determine whether continuous power supply from the 5V DCDC #1 is operating normally in the normal mode after Ignition-On of the electric vehicle. For example, the continuous power supply from the 5V DCDC #1 may be determined to be operating normally based on its voltage being greater than a reference voltage (e.g., 3V) that indicates normal operation, and to be operating abnormally otherwise.

The controller 50 of the BMU 100 (see FIG. 5) may transition to a Sleep Mode upon Ignition-Off without a separate configuration procedure, based on the continuous power supply from the 5V DCDC #1 being determined to be operating normally.

For example, as shown in FIG. 3, in the BMU 100 according to an embodiment of the present disclosure, since the SBC is also in a sleep/off state during the Sleep Mode, a Wake-Up signal from the WCM 20 may be detected only through DIE #2, within the second communication bridge IC 46, that is supplied with power from the 5V DCDC #1. Given that the continuous power supply from the 5V DCDC #1 has already been determined to be normal, the Wake-Up signal may be reliably detected through DIE #2 without concern.

Referring to FIG. 4, in the wireless BMS according to one embodiment of the present disclosure, if the continuous power supply from the 5V DCDC #1 is operating abnormally during the Sleep Mode of the BMU 100, power from the SBC may be supplied to DIE #1 among the two DIEs #1 and #2 in the second communication bridge IC 46, at a time when the SBC is periodically woken up through a pre-configured real-time clock (RTC) operation.

As described above, a controller 50 (see FIG. 5) of the BMU 100 may be configured to continuously or periodically determine whether continuous power supply from the 5V DCDC #1 is operating normally in the normal mode.

Based on a determination that the continuous power supply from the 5V DCDC #1 is operating abnormally, the control unit 50 of the BMU 100 (see FIG. 5) may be configured to perform a separate configuration procedure to utilize power from the SBC before transitioning to a Sleep Mode upon Ignition-Off (IG OFF).

The separate configuration procedure to utilize power from the SBC may include configuring a real-time clock (RTC) operation to periodically wake up the SBC and maintain the SBC in a Wake-Up state for a predetermined period of time.

The separate configuration procedure to utilize power from the SBC may further include deactivating one of the two DIEs within the first communication bridge IC 43. Specifically, the DIE to be deactivated may be the DIE that communicates with DIE #2, within the second communication bridge IC 46, that is supplied with continuous power from the 5V DCDC #1.

Referring to FIG. 4, in the Sleep Mode of the BMU 100, power from the SBC may be supplied to DIE #1 in the second communication bridge IC 46, at a time when the SBC is periodically woken up through a pre-configured RTC operation.

In the present disclosure, the 5V power from the SBC may be utilized as a backup power source for either DIE #1 or DIE #2 within the second communication bridge IC 46 (e.g., ADBMS6822) of the BMU 100. In order to prevent the quiescent current of the BMU 100 from increasing when the SBC remains in a continuously-on state, the RTC operation of the SBC may be activated so that the BMU 100 may monitor cell state information based on the periodic power supply from the SBC.

As a result, since continuous power is not supplied to the second communication bridge IC 46 of the BMU 100, the BMU 100 may have difficulty continuously detecting a Wake-Up signal. However, by utilizing the RTC operation to periodically monitor the cell state information of all CMUs 10, determine abnormalities, and respond accordingly, the diagnostic coverage for battery cell abnormalities may be improved.

Hereinafter, a configuration of the BMU according to one embodiment of the present disclosure will be described with reference to FIG. 5.

FIG. 5 is a diagram schematically illustrating the configuration of a BMU according to an embodiment of the present disclosure. For convenience of explanation, the reference numerals used in FIGS. 2 and 3 are also used in the description of FIG. 5.

The BMU 100 having a power redundancy structure according to an embodiment of the present disclosure may include a control unit 50 (MCU) configured to receive cell state information from one or more CMUs 10 that monitor states of respective battery modules, and to determine whether a battery cell included in each battery module is abnormal based on the cell state information. The BMU 100 may also include a power supply unit 30 (DCDC converter/SBC) configured to supply power to a wireless communication interface unit 40 (particularly, a second communication bridge IC 46) that supports wireless communication between the CMUs 10 and the BMU 100, in two or more different ways even during a Sleep Mode of the BMU 100.

According to an embodiment of the present disclosure, when the BMU 100 is in a Sleep Mode—i.e., when the electric vehicle is in an Ignition-OFF (IG OFF) state—and the power supply from the DCDC converter of the power supply unit 30 (hereinafter, 5V DCDC #1) is operating normally, power from the 5V DCDC #1 may be supplied to DIE #2 within the second communication bridge IC 46.

According to an embodiment of the present disclosure, when the power supply from the 5V DCDC #1 is operating abnormally during the Sleep Mode of the BMU 100, power from the SBC of the power supply unit 30 may be supplied to DIE #1 within the second communication bridge IC 46 at a time when the SBC is periodically woken up through a pre-configured RTC operation in the SBC.

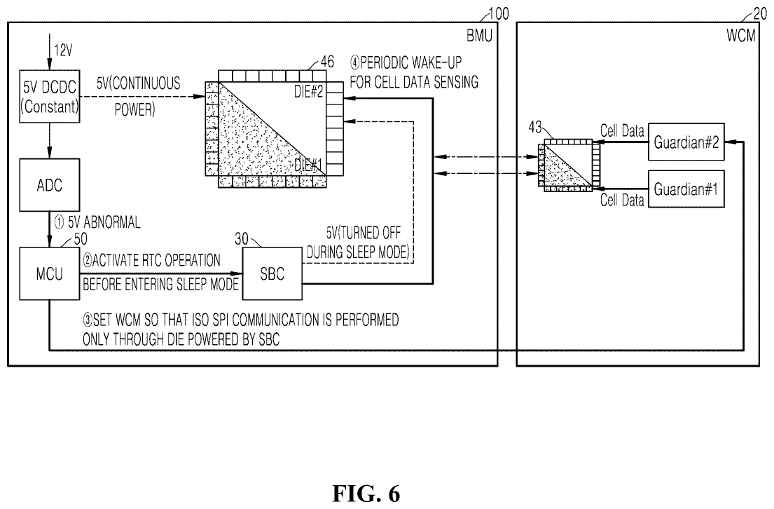

Hereinafter, with reference to FIG. 6, a specific operation of the BMU 100 according to one embodiment of the present disclosure will be described, in which the BMU 100 may operate in response to abnormal power supply from the 5V DCDC #1 during the Sleep Mode.

Referring to FIG. 6, in operation \textcircled{1}, a controller 50 (MCU) may be configured to continuously or periodically determine whether continuous power supply from the 5V DCDC #1 is operating normally in the normal mode after Ignition-On (IG ON) of the electric vehicle.

The controller 50 (MCU) may transition to a Sleep Mode upon Ignition-Off (IG OFF) without a separate configuration procedure, based on the continuous power supply from the 5V DCDC #1 being determined to be operating normally.

Based on a determination in operation \textcircled{1} that the continuous power supply from the 5V DCDC #1 is operating abnormally, the control unit 50 (MCU) may be configured to perform a separate configuration procedure to utilize power from the SBC in operations (2) and (3) before transitioning to a Sleep Mode upon Ignition-Off (IG OFF).

Specifically, in operation \textcircled{2}, the control unit 50 (MCU) may activate an RTC operation such that the SBC is periodically woken up and maintained in a Wake-Up state for a predetermined period of time before entering the Sleep Mode, and may set a Wake-Up timer and maintenance duration.

In addition, in operation \textcircled{3}, the control unit 50 (MCU) may, before entering the Sleep Mode, deactivate one of the two DIEs within the first communication bridge IC 43 in the WCM 20. Specifically, the DIE to be deactivated may be the DIE that communicates with DIE #2, within the second communication bridge IC 46, that is supplied with continuous power from the 5V DCDC #1.

That is, the control unit 50 (MCU) may configure the WCM 20 to allow communication only through the DIE in the first communication bridge IC 43 that communicates with DIE #1, within the second communication bridge IC 46, that is supplied with power from the SBC. This may be achieved by deactivating WCM Guardian #2, which corresponds to the DIE in the first communication bridge IC 43 that communicates with DIE #2 in the second communication bridge IC 46.

Accordingly, if the continuous power supply from the 5V DCDC #1 is operating abnormally, the first communication bridge IC 43 in the WCM 20 may be configured to communicate only through one of the two DIEs therein that communicates with DIE #1, within the second communication bridge IC 46, that is supplied with power from the SBC.

The control unit 50 (MCU) may perform the configuration procedures of operations \textcircled{2} and \textcircled{3} either sequentially or in parallel.

During the Sleep Mode of the BMU 100, when the control unit 50 (MCU) is woken up by a Wake-Up signal generated by the wireless communication interface unit 40, particularly from the WCM 20, that is supplied with power from the 5V DCDC #1, the control unit 50 may receive overall cell state information (also referred to as “cell data” in FIG. 6) from all CMUs 10 through a request-response scheme via the wireless communication interface unit 40, and may determine whether any battery cell is abnormal based on the received information and respond accordingly.

With continued reference to FIG. 6, in operation \textcircled{4}, at a time when the SBC is periodically woken up during the Sleep Mode of the BMU 100, the control unit 50 (MCU) may receive overall cell state information from all CMUs 10 through the wireless communication interface unit 40 that is supplied with power from the SBC, and may determine whether any battery cell is abnormal based on the received information and respond accordingly.

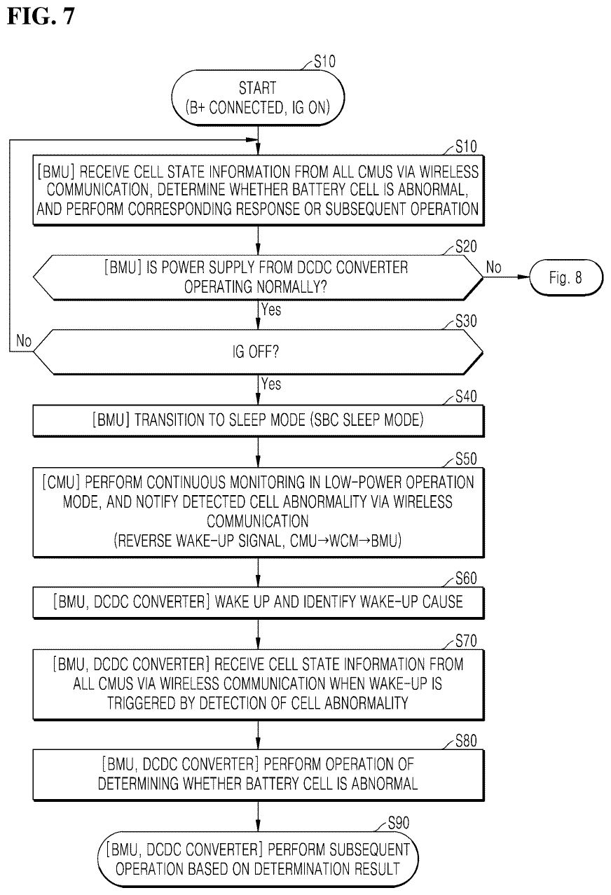

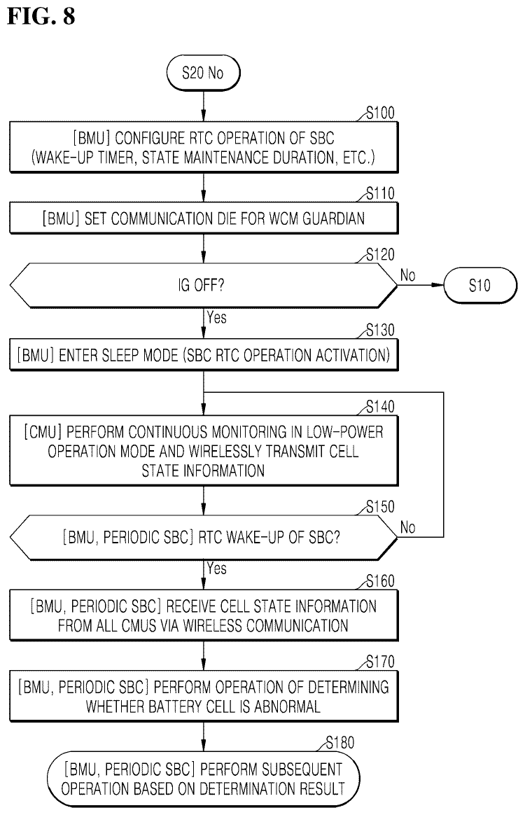

Hereinafter, with reference to FIGS. 7 and 8, a method for operating a wireless battery management system having a power redundancy structure, according to an embodiment of the present disclosure, is described in more detail.

In the following description, it is assumed that the system includes the redundancy structure according to an embodiment of the present disclosure (e.g., the 5V DCDC #1 and the SBC), as described with reference to FIGS. 2-5. For convenience of explanation, the reference numerals used in FIGS. 2-5 are also used in the description of FIGS. 7 and 8.

Referring to FIG. 7, according to a method for operating a wireless BMS having a power redundancy structure according to one embodiment of the present disclosure, in an Ignition-On (IG ON) state under a continuous power (B+) condition supplied by a battery system, respective power from both the 5V DCDC #1 and the SBC may be supplied to each of the two DIEs #1 and #2 of the second communication bridge IC 46.

Referring to FIG. 7, according to a method for operating a wireless BMS having a power redundancy structure according to one embodiment of the present disclosure, in S10, the control unit 50 of the BMU 100 may receive cell state information from all CMUs 10 via wireless communication, may determine whether any battery cell is abnormal based on the received information, and may perform a corresponding response or subsequent operation based on the determination result.

In an operation S20, the control unit 50 of the BMU 100 may determine whether continuous power supply from the 5V DCDC #1 is operating normally in a Normal Mode after an Ignition-On (IG ON).

Upon a Yes determination in the operation S20—i.e., if it is determined that the continuous power supply from the 5V DCDC #1 is operating normally—the BMU 100 may enter a Sleep Mode upon Ignition-Off (IG OFF) without performing a separate configuration procedure, as indicated by a Yes determination in an operation S30 leading to an operation S40. This corresponds to the case of “Sleep—5V continuous power supply is operating normally” illustrated in FIG. 3.

In an operation S50, each CMU 10 may perform continuous monitoring in a low-power operation mode after the BMU 100 enters the Sleep Mode. The CMU 10 that detects a cell abnormality (e.g., overvoltage, undervoltage, or overtemperature of a battery cell) may notify the WCM 20 of the cell abnormality via wireless communication.

Accordingly, in the BMU 100 according to one embodiment of the present disclosure, since the SBC is also in a sleep/off state during the Sleep Mode, a Reverse Wake-Up signal (from the CMU to the BMU through the WCM) may be received or detected through DIE #2, within the second communication bridge IC 46, that is supplied with continuous power from the 5V DCDC #1.

In an operation S60, the control unit 50 of the BMU 100 may be woken up by the Reverse Wake-Up signal and may then identify the cause of the wake-up.

In an operation S70, if the control unit 50 of the BMU 100 is woken up by the Wake-Up signal from the WCM 20 triggered by detection of the cell abnormality, the control unit 50 may receive cell state information from all CMUs 10 via wireless communication using a request-response scheme.

In operations S80 and S90, the control unit 50 of the BMU 100 may determine whether any battery cell is abnormal based on the received information, and may perform a corresponding response or subsequent operation based on the determination result.

Upon a No determination in an operation S20—i.e., if the control unit 50 of the BMU 100 determines that the continuous power supply from the 5V DCDC #1 is operating abnormally—the process may proceed to the sequence illustrated in FIG. 8.

Referring to FIG. 8, according to an embodiment, upon a No determination in the operation S20—i.e., if the control unit 50 of the BMU 100 determines that the continuous power supply from the 5V DCDC #1 is operating abnormally—the control unit 50 may perform a separate configuration procedure in operations S100/S110 to utilize power from the SBC.

In an embodiment, in the operation S100, the control unit 50 of the BMU 100 may activate an RTC operation such that the SBC is periodically woken up and maintained in a Wake-Up state for a predetermined period of time, and may set a Wake-Up timer and maintenance duration.

In an embodiment, the control unit 50 (MCU) of the BMU 100 may configure the WCM 20 to allow communication only through the DIE in the first communication bridge IC 43 that communicates with DIE #1, within the second communication bridge IC 46, that is supplied with power from the SBC. This may be achieved by deactivating WCM Guardian #2, which corresponds to the DIE in the first communication bridge IC 43 that communicates with DIE #2, within the second communication bridge IC 46, that is supplied with continuous power from the 5V DCDC #1.

The control unit 50 of the BMU 100 may perform the operations S100 and S110 either sequentially or in parallel.

In addition, upon a Yes determination in the operation S120—i.e., if an Ignition-Off (IG OFF) is detected—the BMU 100 may enter the Sleep Mode in an operation S130. This corresponds to the case of “Sleep—5V continuous power supply is operating abnormally” illustrated in FIG. 4.

In an operation S140, each CMU 10 may perform continuous monitoring in a low-power operation mode after the BMU 100 enters the Sleep Mode. Each CMU 10 may also transmit cell state information obtained through the monitoring via wireless communication.

Upon a Yes determination in an operation S150—i.e., at a time when the SBC is periodically woken up during the Sleep Mode according to the configuration procedure in operations S100/S110 described above—the control unit 50 of the BMU 100 may receive, in an operation S160, cell state information from all CMUs 10 through DIE #1, within the second communication bridge IC 46, that is supplied with power from the SBC.

In operations S170 and S180, the control unit 50 of the BMU 100 may determine whether any battery cell is abnormal based on the received information, and may perform a corresponding response or subsequent operation based on the determination result.

As described above, in the wireless BMS according to embodiments of the present disclosure, the power redundancy structure may be improved by using power from the SBC, enabling the structure to operate with a single DCDC converter instead of the two DCDC converters used in the existing structure to supply power to the communication interface (e.g., the communication bridge IC of the BMU).

Accordingly, this configuration may improve issues related to an increase in the size and cost of the BMU.

In an embodiment, in order to detect a Wake-Up signal even during the Sleep Mode of the BMU, it is necessary to design the communication interface (e.g., the communication bridge IC of the BMU) to be continuously powered. According to an embodiment of the present disclosure, instead of using two DCDC converters to respectively supply continuous power as in existing structures, one of the continuous power supply paths to the two DIEs is replaced with a power supply path from the SBC. Accordingly, there exists a potential risk that the Wake-Up signal may not be detected during the Sleep Mode if the single DCDC converter supplying continuous power to one of the DIEs in the communication bridge IC fails to operate properly.

However, according to an embodiment of the present disclosure, by performing a preceding process of determining whether the continuous power supply from the DCDC converter is operating normally before entering the Sleep Mode, the potential risk of failing to detect the Wake-Up signal through the single active DIE in the communication bridge IC may be reduced.

According to an embodiment of the present disclosure, if the continuous power supply from the DCDC converter is abnormal, only the power from the SBC may be used to monitor, determine, and respond to the state of battery cells during the Sleep Mode. Accordingly, instead of continuously detecting the Wake-Up signal, the RTC operation may be activated by setting a Wake-Up timer and maintenance duration of the SBC, such that the MCU of the BMU may be periodically woken up to receive all cell state information from all CMUs and thereby monitor the state of the battery cells.

As a result, according to an embodiment of the present disclosure, even when the continuous power supply from the DCDC converter is abnormal in the power redundancy structure for the communication interface (e.g., the communication bridge IC of the BMU), the state of battery cells may still be reliably monitored. This enables fires caused by the battery to be addressed before progressing significantly, thereby greatly reducing damage to property and people.

In addition, in an embodiment, since only one DIE in the communication bridge IC of the BMU operates during the Sleep Mode, the quiescent current of the BMU may be reduced as a result.

As used in the present disclosure (especially in the appended claims), the terms “a/an” and “the” include both singular and plural references, unless the context clearly states otherwise. Also, it should be understood that any numerical range recited in the present disclosure is intended to include all sub-ranges subsumed therein (unless expressly indicated otherwise) and accordingly, the disclosed numeral ranges include every individual value between the minimum and maximum values of the numeral ranges.

The steps or operations of the method according to the present disclosure may be performed in an appropriate order unless a specific order is described or otherwise specified. That is, the present disclosure is not necessarily limited to the order in which the steps are recited. All examples described in the present disclosure or the terms indicative thereof (“for example”, “such as”) are merely to describe the present disclosure in greater detail. Therefore, it should be understood that the scope of the present disclosure is not limited to the example embodiments described above or by the use of such terms unless limited by the appended claims. Also, it should be apparent to those having ordinary skilled in the art that various modifications, combinations, and alternations may be made depending on design conditions and factors within the scope of the appended claims or equivalents thereof.

The present disclosure is thus not limited to the example embodiments described above. Rather, the present disclosure is intended to include the following appended claims, and all modifications, equivalents, and alternatives falling within the spirit and scope of the following claims.

The present disclosure described as above is not limited by the aspects described herein and the accompanying drawings. It should be apparent to those having ordinary skill in the art that various substitutions, changes and modifications that are not described herein but are still within the spirit and scope of the present disclosure may be made. Therefore, the scope of the present disclosure is defined not by the detailed description, but by the claims and their equivalents, and all variations within the scope of the claims and their equivalents are to be construed as being included in the present disclosure.

What is claimed is:

1. A wireless battery management system comprising:
at least one cell monitoring unit (CMU) configured to monitor a state of each battery module among one or more battery modules in a battery system;
a battery management unit (BMU) configured to determine whether a battery cell included in each battery module, among the one or more battery modules, is abnormal based on cell state information provided by the CMU; and
a power supply unit configured to supply power in two or more different ways to a wireless communication interface unit that is configured to support wireless communication between the CMU and the BMU.

2. The wireless battery management system of claim 1, wherein the power supply unit includes:
a direct current to direct current (DCDC) converter configured to supply continuous power to the wireless communication interface unit; and
a system basis chip (SBC) configured to step down input power from a vehicle to a voltage level suitable for each component within the BMU and to supply the stepped-down input power to each component within the BMU.

3. The wireless battery management system of claim 1, wherein the wireless communication interface unit comprises:
a first communication bridge integrated circuit (IC) implemented in a wireless communication module (WCM) and configured to perform wireless communication with the CMU; and
a second communication bridge IC implemented in the BMU and configured to receive the cell state information from the CMU through communication with the first communication bridge IC.

4. The wireless battery management system of claim 3, wherein:
the second communication bridge IC includes two independent dies configured to communicate with the first communication bridge IC; and
the power supply unit includes a direct current to direct current (DCDC) converter and a system basis chip (SBC), wherein the DCDC converter and the SBC is each configured to supply power to a corresponding one die among the two independent dies.

5. The wireless battery management system of claim 4, wherein:
in an active mode of the BMU, respective power from the DCDC converter and the SBC is supplied to each of the two independent dies included in the second communication bridge IC; and
in a Sleep Mode of the BMU, power from one of the DCDC converter or the SBC is supplied to one of the two independent dies.

6. A battery management unit (BMU), the BMU comprising:
a control unit configured to
receive cell state information from at least one cell monitoring unit (CMU) that is configured to monitor a state of each battery module among one or more battery modules, and
determine whether a battery cell included in each battery module, among the one or more battery modules, is abnormal based on the received cell state information; and
a power supply unit configured to supply power in two or more different ways to a wireless communication interface unit that is configured to support wireless communication between the CMU and the BMU.

7. The BMU of claim 6, wherein the power supply unit includes:
a direct current to direct current (DCDC) converter configured to supply continuous power to the wireless communication interface unit; and
a system basis chip (SBC) configured to step down input power from a vehicle to a voltage level suitable for each component within the BMU and to supply the stepped-down input power to each component within the BMU.

8. The BMU of claim 6, wherein the wireless communication interface unit includes:
a first communication bridge integrated circuit (IC) implemented in a wireless communication module (WCM) and configured to perform wireless communication with the CMU; and
a second communication bridge IC implemented in the BMU and configured to receive cell state information from the CMU through communication with the first communication bridge IC.

9. The BMU of claim 8, wherein:
the second communication bridge IC includes two independent dies configured to communicate with the first communication bridge IC; and
the power supply unit includes a direct current to direct current (DCDC) converter and a system basis chip (SBC), wherein the DCDC converter and the SBC is each configured to supply power to a corresponding die among the two independent dies.

10. The BMU of claim 9, wherein the power supply unit is configured to:
based on normal operation of continuous power supply by the DCDC converter in a Sleep Mode of the BMU, supply continuous power from the DCDC converter to a corresponding dies among the two independent dies; and
based on abnormal operation of the continuous power supply by the DCDC converter in the Sleep Mode of the BMU, supply power from the SBC to a corresponding dies among the two independent dies based on periodic wake-up of the SBC triggered by a pre-configured real-time clock (RTC) operation.

11. The BMU of claim 10, wherein the first communication bridge IC includes two dies configured to communicate in a one-to-one manner with the two independent dies within the second communication bridge IC, and wherein the first communication bridge IC is configured to communicate, based on abnormal operation of continuous power supply by the DCDC converter, only through one of the two dies within the first communication bridge IC that communicates with a dies, within the second communication bridge IC, that is supplied with power from the SBC.

12. The BMU of claim 10, wherein the control unit is configured to, based on being woken up by the wireless communication interface unit operating with continuous power from the DCDC converter during the Sleep Mode of the BMU, i) receive cell state information from all CMUs through the wireless communication interface unit and ii) determine, based on the received cell state information, whether each battery cell is abnormal.

13. The BMU of claim 10, wherein the control unit is configured to, based on periodic wake-up of the SBC during the Sleep Mode of the BMU, i) receive cell state information from all CMUs through the wireless communication interface unit operating with power supplied from the SBC and ii) determine, based on the received cell state information, whether each battery cell is abnormal.

14. A method for operating a wireless battery management system (BMS), the method comprising:
continuously monitoring, by at least one cell monitoring unit (CMU), a state of each battery module among one or more battery modules;
determining, by a battery management unit (BMU), whether a battery cell included in each battery module, among the one or more modules, is abnormal based on cell state information monitored by the at least one CMU; and
operating a wireless communication interface unit in BMU using power supplied from at least one of a DCDC converter configured to provide continuous power and a system basis chip (SBC), wherein the wireless communication interface unit is configured to support wireless communication between the CMU and the BMU.

15. The method of claim 14, wherein the wireless communication interface unit includes:
a first communication bridge IC implemented in a wireless communication module (WCM) and configured to perform wireless communication with the CMU; and
a second communication bridge IC implemented in the BMU and configured to receive cell state information from the CMU through communication with the first communication bridge IC.

16. The method of claim 15, further comprising:
determining, by a control unit of the BMU, whether continuous power supply by the DCDC converter is operating normally after Ignition-On;
transitioning, by the control unit of the BMU, to a Sleep Mode upon Ignition-Off without a separate configuration procedure based on the continuous power supply being determined to be operating normally; and
transitioning, by the control unit of the BMU, to a Sleep Mode upon Ignition-Off after performing a separate configuration procedure to utilize power from the SBC, based on the continuous power supply being determined to be operating abnormally.

17. The method of claim 16, wherein:
the second communication bridge IC includes two independent dies configured to communicate with the first communication bridge IC;
the first communication bridge IC includes two dies that communicate in a one-to-one manner with the two independent dies within the second communication bridge IC; and
the separate configuration procedure to utilize power from the SBC includes configuring a real-time clock (RTC) operation such that the SBC is periodically woken up and remains in a wake-up state for a predetermined period of time.

18. The method of claim 17, wherein:
the second communication bridge IC comprises two independent dies configured to communicate with the first communication bridge IC, wherein respective power from the DCDC converter and the SBC is supplied to each of the two independent dies included in the second communication bridge IC,
the first communication bridge IC comprises two dies configured to communicate in a one-to-one manner with the two independent dies within the second communication bridge IC; and
the separate configuration procedure to utilize power from the SBC includes deactivating one of the two dies within the first communication bridge IC, the die to be deactivated being the die that communicates with a die, within the second communication bridge IC, that is supplied with continuous power from the DCDC converter.
